(19) United States
(12) Patent Application Publication
(10) Pub. No.: US 2012/0198485 A1
(43) Pub. Date: Aug. 2, 2012

(54) LASER HOLDER AND OPTICAL PICKUP PROVIDED WITH SAME

(75) Inventor: Tetsuo NISHIDATE, Osaka (JP)

(73) Assignee: Funai Electric Co., Ltd.

(21) Appl. No.: 13/349,698

(22) Filed: Jan. 13, 2012

(30) Foreign Application Priority Data
Jan. 28, 2011 (JP) 2011-017212

(51) Int. Cl. H01S 5/022; G11B 7/123

(52) U.S. Cl. 720/689; 362/382; G9B/7.108

(57) ABSTRACT

A laser holder is used for holding a semiconductor laser, and is obtained by working of a metal sheet. The laser holder is provided with a step formed by folding of a metal sheet; and a positioning holding section capable of holding the semiconductor laser in a positioned state using the step, the positioning holding section provided on the metal sheet.

This application is based on Japanese Patent Application No. 2011-017212 filed on Jan. 28, 2011, the contents of which are hereby incorporated by reference.

### BACKGROUND OF THE INVENTION

1. Field of the Invention

The present invention relates to a laser holder for holding a semiconductor laser (device). The invention also relates to an optical pickup provided with a laser holder of such description.

2. Description of Related Art

In the conventional art, optical pickups are utilized when reading information recorded onto an optical disk such as a Blu-Ray disc (BD), digital versatile disc (DVD), compact disc (CD), or the like, or to write information thereon. The optical pickup is provided with a semiconductor laser for irradiating the optical disk with a laser beam.

Frame type semiconductor lasers are conventionally known in the art as semiconductor lasers provided to optical pickups. A frame type semiconductor laser has a structure in which a semiconductor laser chip is placed on an upper face of a tabular metal frame, and a resin is outsert-molded so as to enclose the semiconductor laser chip on the metal frame.

A semiconductor laser placed on an optical pickup is sometimes placed in a laser holder for attachment to a base member of an optical pickup. In such configurations, the laser holder is sometimes made of metal with a view to increasing radiation of heat generated by the semiconductor laser, as shown in JP-A-2008-146785. In JP-A-2008-146785 there is disclosed a configuration in which a semiconductor laser is secured by being press-fit within a metal holder that has been die-cast from zinc or the like.

### SUMMARY OF THE INVENTION

However, according to the configuration shown in JP-A-2008-146785, a structure is adopted whereby the frame type semiconductor laser is secured by being press-fit into a laser holder. In such a configuration, the tabular metal frame constituting the semiconductor laser may deform under press-fitting. In a worst case scenario, the semiconductor laser chip placed on the metal frame may detach from the metal frame.

Frame type semiconductor lasers are more advantageous than can-package semiconductor lasers in regard to cost. Therefore, where a frame type semiconductor laser is employed, it is preferable to avoid a laser holder of high cost, and it is desirable for the laser holder to be manufactured at as low a cost as possible.

By “can-package semiconductor laser” is meant a structure in which a semiconductor laser chip is placed on a metal stem, and the semiconductor laser chip is protected by a metal cap of cylindrical shape. In order for laser light to be emitted, the cylindrical metal cap is structured so as to be provided with, for example, a glass window or an opening.

With the foregoing in view, it is an object of the present invention to offer a laser holder suitable for a frame type semiconductor laser. More particularly, it is an object of the invention to offer a laser holder that readily ensures radiation of heat generated by a frame type semiconductor laser. Another object of the invention is to offer a laser holder affording ease of attachment of a frame type semiconductor laser. Yet another object of the invention is to offer a configuration that readily enables a reduction in cost of a laser holder for holding a frame type semiconductor laser. A further object of the present invention is to offer an optical pickup provided with such a laser holder, the optical pickup being highly reliable and capable of being manufactured at low cost.

The laser holder of the present invention directed to accomplishing the aforedescribed object is a laser holder for holding a semiconductor laser, configured to be provided with a step formed by folding a metal sheet; and a positioning holding section capable of holding the semiconductor laser in a positioned state using the step, the positioning holding section being provided on the metal sheet.

According to the present configuration, the laser holder can be formed by working a metal sheet, and therefore can be manufactured inexpensively. Also, according to the present configuration, because the laser holder is made of a metal sheet, radiation of the heat of the semiconductor laser is readily ensured. Moreover, the laser holder of the present configuration utilizes for positioning purposes a step obtained by folding a metal sheet, making it possible to hold the semiconductor laser in a positioned state without press-fitting. Because of this, as long as the laser holder of the present configuration is employed, there is minimal likelihood of the semiconductor laser breaking during attachment of the semiconductor laser; moreover, the semiconductor laser is readily attached.

In the laser holder of the aforedescribed configuration, the step preferably has a height equivalent to the thickness of the metal sheet. According to the present configuration, the laser holder is readily worked.

In the laser holder of the aforedescribed configuration, the semiconductor laser may be a frame type semiconductor laser having a metal frame section on one face of which a semiconductor laser chip is placed, and a resin section provided so as to surround the semiconductor laser chip. The laser holder of the present configuration readily ensures heat radiation properties for the frame type semiconductor laser, and readily affords ease of attachment.

The laser holder of the aforedescribed configuration may be configured to be further provided with an attachment section for use when the laser holder is attached to another member, and the positioning holding section may be configured to hold the semiconductor laser such that the semiconductor laser is vertically disposed with respect to the attachment section. The laser holder of the present configuration is readily implemented in an optical pickup. In this configuration, a protecting wall for protecting the semiconductor laser chip of the semiconductor laser held in the positioning holding section may be vertically disposed on the attachment section.

In the laser holder of the aforedescribed configuration, the metal sheet constituting the laser holder may be configured to be provided with a first portion serving as the attachment section, a second portion folded so as to overlap in a state of contact with the first portion, the second portion being continuous with the first portion, a third portion folded back so as to be vertically disposed with respect to the first portion, the third portion being continuous with the second portion; and a fourth portion folded so as to overlap in a state of contact with the third portion, and forming the positioning holding section together with the third portion, the fourth portion being continuous with the third portion.

The optical pickup of the present invention directed to accomplishing the aforedescribed object is configured to be provided with a base member in which an optical member is placed, the laser holder of the aforedescribed configuration being attached to the base member.

According to the optical pickup of the present configuration, costs of the semiconductor laser and laser holder used therein are readily reduced, and the cost of the optical pickup is readily reduced as well. The optical pickup of the present configuration can also offer a highly reliable optical pickup unlikely to experience malfunction, failure, or other adverse events because sufficient heat radiation properties of the semiconductor laser can be ensured.

As set forth above, according to the present invention, a laser holder suitable for holding a frame type semiconductor laser can be offered inexpensively. The laser holder of the invention readily ensures radiation of heat produced by a frame type semiconductor laser. A frame type semiconductor laser is readily attached to the laser holder of the invention. According to the invention, it is possible to offer an optical pickup that is highly reliable and that can be manufactured at low cost.

### BRIEF DESCRIPTION OF THE DRAWINGS

FIG. 1 is a schematic perspective view illustrating the laser holder of the present embodiment;

FIG. 2 is a development view of the laser holder shown in FIG. 1;

FIG. 3 is a schematic plan view taken along direction A of FIG. 1, showing the laser holder of the present embodiment holding a semiconductor laser;

FIG. 4 is a plan view showing a schematic configuration of an optical pickup provided with the laser holder of the present embodiment; and

FIG. 5 is a schematic plan view showing a configuration of a surrounding area of the laser holder when viewed along arrow Z in FIG. 4.

### DETAILED DESCRIPTION OF PREFERRED EMBODIMENTS

Embodiments implementing the present invention in a laser holder and in an optical pickup are described in detail below with reference to the drawings.

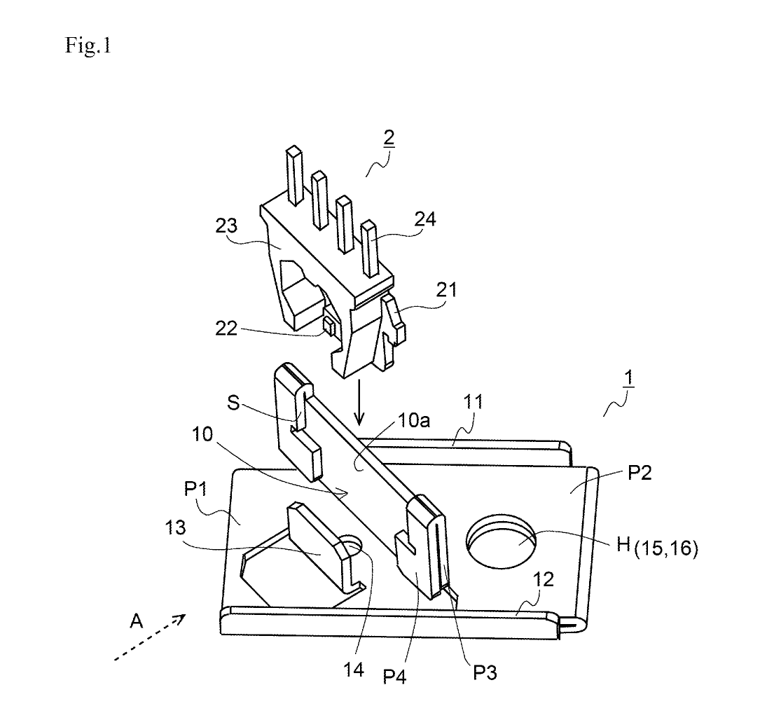

FIG. 1 is a schematic perspective view describing the laser holder of the present embodiment, and also shows a semiconductor laser prior to insertion into the laser holder.

A semiconductor laser 2, as shown in FIG. 1, is provided with a tabular metal frame section 21, a semiconductor laser chip 22 placed on a face of the metal frame section 21, a resin section 23 outsert-molded onto the metal frame section 21 so as to surround the semiconductor laser chip 22, and a plurality of terminal pins 24 secured by the resin section 23. This semiconductor laser 2 is referred to as a frame type semiconductor laser. Specifically, a laser holder 1 of the present embodiment is a laser holder suitable for a frame type semiconductor laser.

In order for heat generated by the semiconductor laser chip 22 to be efficiently radiated, the metal frame section 21 is preferably formed of a metal having good heat radiation properties. The semiconductor laser chip 22 used in the present embodiment is one provided with an emission point for emitting a laser beam for a DVD (for example, a laser beam of a 650 nm wavelength band) and an emission point for emitting a laser beam for a CD (for example, a laser beam of a 780 nm wavelength band). However, this is merely an example; the laser beam wavelength emitted by the semiconductor laser chip 22 may be modified appropriately according to the intended use. The number of emission points the semiconductor laser chip 22 has is not limited to the configuration of the present embodiment, and may be modified appropriately (to one, or to three or more) according to the intended use as well.

The resin section 23 is preferably formed of a resin with heat resistance high enough to withstand the heat generated by the semiconductor laser chip 22. As previously mentioned, the resin section 23 is provided so as to surround the semiconductor laser chip 22, and, more specifically, is provided in a section thereof with an opening for a laser beam from the semiconductor laser chip 22 to be emitted to the outside (in the semiconductor laser 2 shown in FIG. 1, a opening is provided to the lower side). The thickness of the resin section 23 is sufficiently greater than the thickness of the semiconductor laser chip 22, so that the semiconductor laser chip 22 can be protected.

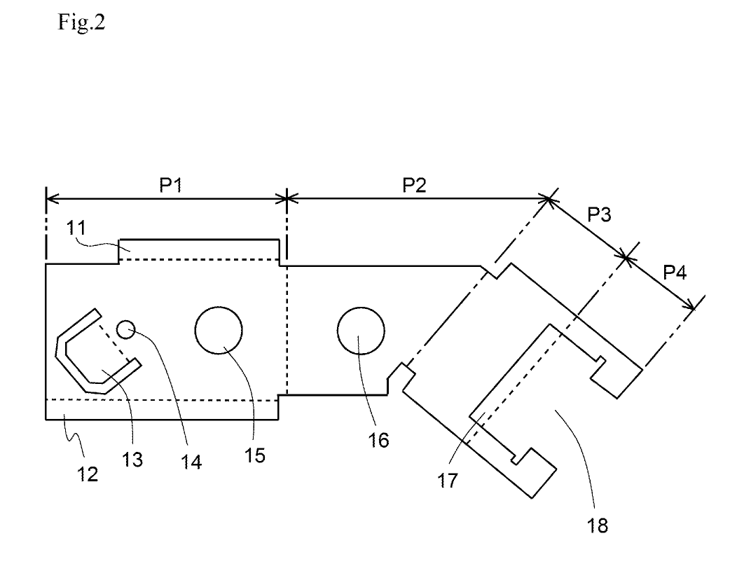

The laser holder 1 of the present embodiment for holding the semiconductor laser 2 with the configuration discussed above is made of a metal sheet, and is obtained by folding back the metal sheet and making holes in the metal sheet (by working of the metal sheet). FIG. 2 is a development view of the laser holder shown in FIG. 1. In FIG. 2, the broken line portions show sites of valley folding, and the single-dot and dash line portions show sites of mountain folding.

As shown in FIG. 2, the metal sheet forming the laser holder 1 is demarcated into a first portion P1, a second portion P2, a third portion P3, and a fourth portion P4. The first portion P1 is continuous with the second portion P2 only. The second portion P2 is continuous with the first portion P1 and with the third portion P3. The third portion P3 is continuous with the second portion P2 and with the fourth portion P4. The fourth portion P4 is continuous with the third portion P3 only.

The first portion P1 is a portion serving as a foundation of the laser holder 1, and when the laser holder 1 is attached to another member, the first portion P1 will be attached to the other member. Specifically, this first portion P1 corresponds to the “attachment section” of the invention. Of two side faces of this first portion P1 along the lengthwise direction (the left-right direction in FIG. 2), a first fold-back section 11 is formed on one of the faces, and a second fold-back section 12 is formed on the other. The first fold-back section 11 and second fold-back section 12 are valley-folded at the broken line positions in FIG. 2, so as to be oriented in a substantially vertical direction from the state shown in FIG. 2.

The second fold-back section 12 is provided so as to extend in the lengthwise direction of the first portion P1 from a first end (the right side in FIG. 2) to the other end (the left side in FIG. 2), whereas the first fold-back section 11 extends only from the first end to a position short of the other end.

The first portion P1 is provided toward the other end in the lengthwise direction (toward the left in FIG. 2) with a cutout of a shape resembling an inclined U, thereby forming a third fold-back section 13. This third fold-back section 13 is valley-folded at the broken line position in FIG. 2, so as to be oriented in a substantially vertical direction from the state shown in FIG. 2. A first through-hole 14 of substantially circular shape in plan view is formed in the first portion P1 in proximity to the third fold-back section 13, and a second through-hole 15 of substantially circular shape in plan view and larger than the first through-hole 14 is formed toward the first end in the lengthwise direction (toward the right in FIG. 2).

The second portion P2 is formed in a substantially trapezoidal shape, and is valley-folded at a position serving as the boundary with first portion P1 to overlap the first portion P1 in contact therewith. The second portion P2 is smaller than the first portion P1, and in a state of the second portion P2 overlapping the first portion P1, an area of the first portion P1 lying toward the other end (toward the left in FIG. 2) is left exposed, uncovered by the second portion P2.

A third through-hole 16 of substantially circular shape in plan view is formed in a substantially central section of the second portion P2. With the second portion P2 overlapping the first portion P1, this third through-hole 16 is provided so as to overlap the entirety of the second through-hole 15 provided in the first portion P1. The third through-hole 16 is provided in a size substantially identical to that of the first through-hole 15.

The third portion P3 provided in a substantially rectangular shape is provided so as to be linked with an oblique side section of the second portion P2, which has been formed with a substantially trapezoidal shape, there being a mountain-fold on the oblique side section (boundary position). In a state of the second portion P2 overlapping the first portion P1, the third portion P3 is folded back so as to be vertically disposed with respect to the first portion P1 (and the second portion P2). A cutout 17 of substantially rectangular shape is formed in the third portion P3, in proximity to a portion thereof serving as a boundary with the fourth portion P4.

The fourth portion P4 has a shape produced by cutting out a substantially T-shaped area 18 (linked with the cutout 17) from a substantially rectangular area. This fourth portion P4 is valley-folded at a position serving as a boundary with the third portion P3, and overlaps in a state of being in contact with the third portion P3. Specifically, this fourth portion P4 is also vertically disposed with respect to the first portion P1 (see FIG. 1).

The fourth portion P4 overlaps the third portion P3, thereby forming a step S with a thickness equivalent to that of the sheet. A space 10 surrounded by walls constituting the step S (see FIG. 1) is used as a holding section for holding the semiconductor laser 2. The walls constituting the step S are utilized as positioning faces when the semiconductor laser 2 is to be held, and the semiconductor laser 2 is held in a state of being positioned within the space 10. Specifically, the space 10 is an example of the positioning holding section of the invention. Hereinbelow, the space 10 will be denoted as a positioning holding section 10.

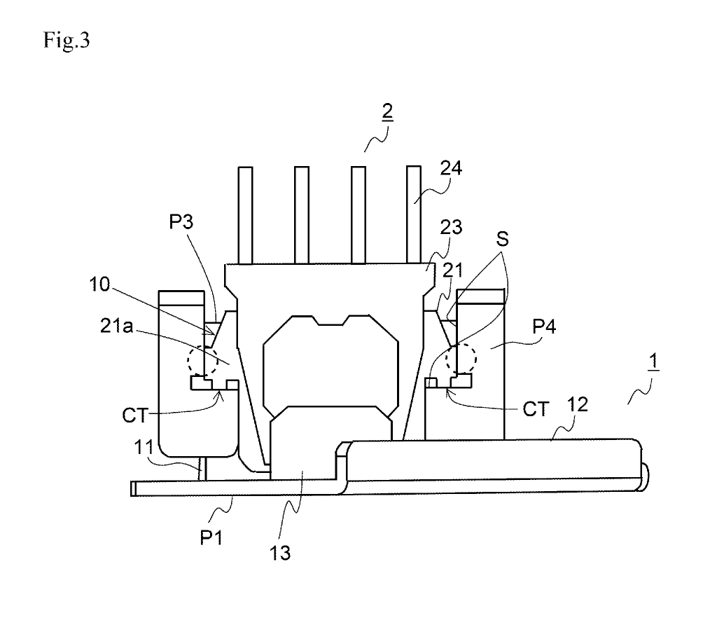

FIG. 3 is a schematic plan view taken along direction A of FIG. 1, showing the laser holder of the present embodiment holding a semiconductor laser. The direction along direction A of FIG. 1 corresponds to a direction in which the semiconductor laser is viewed from the front face side. As shown in FIG. 3, the semiconductor laser 2 is held in the laser holder 1 such that the semiconductor laser chip 22 is oriented downward and the terminal pins 24 are oriented upward.

The distance across the step S (the walls constituting the step S) in the widthwise direction of the positioning holding section 10 (the left-right direction in FIG. 3) is substantially equal to (slightly greater than) the width of the semiconductor laser 2 (in more detail, the metal frame section 21). Because of this, the step S is utilized (a wall constituting the step S is employed as the positioning face) for widthwise positioning of the semiconductor laser 2 held in the positioning holding section 10.

As shown in FIG. 3, the metal frame section 21 of the semiconductor laser 2 is configured to have a wide upper section and a narrow lower section, in a case where the semiconductor laser 2 oriented so as to be held in the positioning holding section 10. Because of this, in a case where the semiconductor laser 2 is arranged in the positioning holding section 10, a projecting portion 21a of the metal frame section 21 (a portion projecting with respect to the lower section in the upper section) abuts a wall constituting the step S (abuts the portion shown by reference symbol CT in FIG. 3), the semiconductor laser 2 being positioned in the vertical direction.

Positioning in the direction perpendicular to the plane of the drawing in FIG. 3 is accomplished employing a bottom face 10a of the positioning holding section 10, rather than the step S (see FIG. 1). Here, the bottom face 10a of the positioning holding section 10 corresponds to the exposed portion of the third portion P3, i.e., the portion thereof not covered by the fourth portion P4, on the face against which the fourth portion P4 overlaps.

An adhesive of ultraviolet curing type (UV adhesive), for example, is employed for maintaining the semiconductor laser 2 in a positioned state. Specifically, the semiconductor laser 2 is arranged in the positioning holding section 10 so as to be positioned in the widthwise direction and in the vertical direction. The semiconductor laser 2 is then held down onto the bottom face 10a of the positioning holding section 10 by a jig so as to be positioned in a direction perpendicular to the plane of the drawing (FIG. 3). Thereafter, a UV adhesive is applied to a predetermined adhesion site, and the application site is irradiated with ultraviolet. The UV adhesive is cured thereby, and the semiconductor laser 2 will be held in a positioned state in the laser holder 1 even if the jig is removed. In this state, an aimed laser beam will be emitted from the semiconductor laser 2 through the first through-hole 14.

There are no particular limitations as to the adhesion site for the UV adhesive; in the present embodiment, the adhesion sites are portions surrounding the broken line circles in FIG. 3.

As shown in FIG. 3, in a state of the semiconductor laser 2 being positioned and held in the positioning holding section 10, the semiconductor laser chip 22 of the semiconductor laser 2 is covered by the third fold-back section 13. This configuration affords protection of the semiconductor laser chip 22 by reducing the likelihood of dust infiltrating toward the semiconductor laser chip 22 of the semiconductor laser 2, among other reasons. Specifically, the third fold-back section 13 is an example of the protecting wall of the invention.

This third fold-back section 13 is not an essential component; configurations not provided with the third fold-back section 13 are acceptable as well.

The laser holder 1 holds the semiconductor laser 2 such that the metal frame section 21 of the semiconductor laser 2 is inclined with respect to the lengthwise direction, as viewed from above. This incline is determined with regard to the configuration of the optical pickup to which the laser holder 1 is attached. The aforedescribed incline at which the semiconductor laser 2 is held can be modified according to the configuration of the optical pickup, and the configuration of the laser holder 1 may be modified appropriately depending on this modification.

The semiconductor laser 2 is attached positioned in the laser holder 1 configured as above, without being press-fit into the laser holder 1. The semiconductor laser 2 is accordingly attached to the laser holder 1 in a simple fashion, and is unlikely to get damaged. In the laser holder 1, most of the back face of the metal frame section 21 of the semiconductor laser 2 (the face on the opposite side from the face on which the semiconductor laser chip 22 is placed) can be caused to contact the metal sheet constituting the laser holder 1; therefore, high heat radiation properties can be ensured. The laser holder 1 is made of a metal sheet, and is accordingly inexpensive.

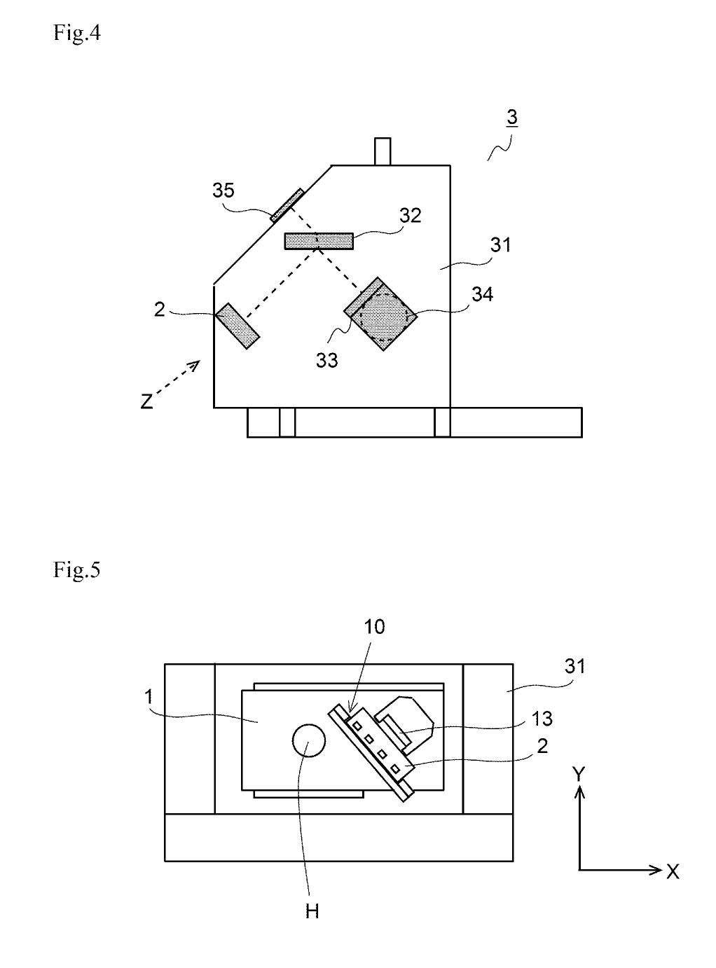

Next, an optical pickup provided with the laser holder 1 of the present embodiment configured as above will be described with reference to FIG. 4 and FIG. 5. FIG. 4 is a plan view showing a schematic configuration of an optical pickup provided with the laser holder of the present embodiment. FIG. 5 is a schematic plan view showing a configuration in an area surrounding the laser holder when viewed along arrow Z in FIG. 4. FIG. 4 is a view from the back face side of the optical pickup (the side to which a laser beam directed upward by a raising mirror 33 is oriented downward).

The optical pickup 3 of the present embodiment has a base member 31 for placement of the semiconductor laser 2 (held in the laser holder 1), optical members 32 to 34, a photoreceptor element 35, and the like. The optical members to be placed on the base member 31 include a beam splitter 32, the raising mirror 33, and an objective lens 34. In FIG. 4, the objective lens 34 is arranged on the far side in a direction perpendicular to the plane of the drawing (the far side relative to the plane of the drawing), and is therefore shown by a broken line.

In the optical pickup 3, a laser beam emitted by the semiconductor laser 2 is partially reflected by the beam splitter 32. The reflected laser beam is reflected by the raising mirror 33, and the direction in which the beam propagates is converted to a direction perpendicular to an information recording face of an optical disk that is not shown (in FIG. 4, arranged to the far side relative to the plane of the drawing). The laser beam reflected by the raising mirror 33 is focused by the objective lens 34 onto the information recording face of the optical disk.

The objective lens 34, which has been placed on an objective lens actuator (not shown), is placed on the base member 31. The objective lens actuator is a device enabling the objective lens 34 to move in a focus direction and a tracking direction. Here, the focus direction is a direction perpendicular to the information recording face of the optical disk (direction perpendicular to the plane of the drawing in FIG. 4), and the tracking direction is a direction parallel to a radial direction of the optical disk (the left-right direction in FIG. 4). Through the use of the objective lens actuator, it is possible to control the focal point of the objective lens 34 (perform focus control) so that it is constantly positioned on the information recording face. Also, through the use of the objective lens actuator, it is possible to control the light spot focused onto the information recording face by the objective lens 34 so that it constantly follows the track of the optical disk (tracking control).

The laser beam focused onto the information recording face of the optical disk by the objective lens 34 reflects off the information recording face. The reflected light (returning light) is transmitted in succession through the objective lens 34, the raising mirror 33, and the beam splitter 32, before reaching the photoreceptor element 35. The photoreceptor element 35 functions as photoelectric conversion means for converting a light signal received in a photoreceptor area into an electrical signal. The electrical signal output from the photoreceptor element 35 undergoes signal processing to become a playback signal, a servo signal, or the like.

In the present embodiment, as mentioned previously, the semiconductor laser 2 is configured as a two-wavelength laser for emitting a DVD laser beam and a CD laser beam. For this reason, the photoreceptor element 35 is provided with a DVD photoreceptor area and a CD photoreceptor area.

In the optical pickup 3 configured as described above, the semiconductor laser 2 is placed on the base member 31 in a state of being held in the laser holder 1 (see FIG. 5). The laser holder 1 is, for example, adhesively fixed to the base member 31. The laser holder 1 is adhesively fixed to the base member 31 using a UV adhesive or the like.

When the optical pickup 3 is assembled, the position of the semiconductor laser 2 is adjusted so that the optical axis thereof is brought to a target position. The position is adjusted by sliding the laser holder 1 within the XY plane in FIG. 5. This sliding movement is performed using a jig, and a jig hole H (formed when the second through-hole 15 and the third through-hole 16 are overlapped) into which the jig is inserted is formed in the laser holder 1. The position of the semiconductor laser 2 is adjusted while the jig is inserted into the jig hole H and the laser holder 1 is moved. Once the optimum position of the semiconductor laser 2 has been determined, a UV adhesive applied to a predetermined site is irradiated with ultraviolet. The laser holder 1 is thereby fixed to the base member 31 by the UV adhesive.

In the optical pickup 3, a metal cover (not shown) is laid over the base member 31 in order for the optical members placed on the base member 31 to be protected from dust. The metal cover should also be made to perform the role of radiating heat generated by the semiconductor laser chip 22, the laser holder 1 and the metal cover preferably being placed in contact.

The embodiment shown above is merely one example of the invention; the laser holder and optical pickup of the invention are not limited to the configuration shown above.

For example, the embodiment shown above is configured so that the first fold-back section 11 and the second fold-back section 12 are provided to the laser holder 1 made of a metal sheet. However, the invention is not limited to this configuration. Specifically, the first fold-back section 11 and the second fold-back section 12 need not be provided. However, providing these fold-back sections 11, 12 is expected to increase the strength of the laser holder 1, prevent position shift during folding-back processing, and offer other advantages. It is accordingly preferable to furnish the first fold-back section 11 and the second fold-back section 12.

Whereas the embodiment shown above is configured so as to be provided with the laser holder 1 with the jig hole H, the invention is not limited to this configuration; the jig hole H need not be provided.

Moreover, the embodiment shown above is configured such that the metal sheet constituting the laser holder 1 has the first portion P1, the second portion P2, the third portion P3, and the fourth portion P4. However, the invention is not limited to this configuration; specifically, another acceptable configuration is one wherein, e.g., of the four portions P1 to P4, the second portion P2 overlapping in a state of contact with the first portion P1 is not provided. In this case, the shapes of the first portion P1 and other portions may be modified appropriately from the shapes shown in the present embodiment. However, providing the second portion P2 as taught in the present embodiment is advantageous in terms of increasing the strength of the laser holder 1, or providing other merits.

Whereas the optical pickup in the embodiment shown above is DVD- and CD-compatible, it shall be apparent that optical disk types compatible with an optical pickup implementing the invention are not limited to those shown in the present embodiment. As much as the laser holder of the invention was shown above as being implemented in an optical pickup, it shall be apparent that the laser holder of the invention may be implemented in other optical devices as well.

What is claimed is:

1. A laser holder for holding a semiconductor laser, comprising:
a step formed by folding of a metal sheet; and
a positioning holding section capable of holding the semiconductor laser in a positioned state using the step, the positioning holding section provided on the metal sheet.

2. The laser holder of claim 1, wherein
the step has a height equivalent to the thickness of the metal sheet.

3. The laser holder of claim 1, wherein
the semiconductor laser is a frame type semiconductor laser having a metal frame section on one face of which a semiconductor laser chip is placed, and a resin section provided so as to surround the semiconductor laser chip.

4. The laser holder of claim 1,
further provided with an attachment section for use when the laser holder is attached to another member,
wherein the positioning holding section holds the semiconductor laser such that the semiconductor laser is vertically disposed with respect to the attachment section.

5. The laser holder of claim 4 wherein
a protecting wall for protecting the semiconductor laser chip of the semiconductor laser held in the positioning holding section is vertically disposed on the attachment section.

6. The laser holder of claim 4 wherein
the metal sheet constituting the laser holder is provided with
a first portion serving as the attachment section;
a second portion folded so as to overlap in a state of contact with the first portion, the second portion being continuous with the first portion,
a third portion folded back so as to be vertically disposed with respect to the first portion, the third portion being continuous with the second portion; and
a fourth portion folded so as to overlap in a state of contact with the third portion, and forming the positioning holding section together with the third portion, the fourth portion being continuous with the third portion.

7. An optical pickup comprising:
a base member in which an optical member is placed; and
a laser holder provided for holding a semiconductor laser, and attached to the base member;
wherein
the laser holder is provided with:
a step formed by folding of a metal sheet; and
a positioning holding section capable of holding the semiconductor laser in a positioned state using the step, the positioning holding section being provided on the metal sheet.
